(19) United States
(12) Patent Application Publication
(10) Pub. No.: US 2026/0089905 A1
(43) Pub. Date: Mar. 26, 2026

(54) ELECTROMAGNETIC WAVE SHIELDING MATERIAL, ELECTRONIC COMPONENT, AND ELECTRONIC APPARATUS

(71) Applicant: FUJIFILM Corporation, Tokyo (JP)

(72) Inventor: Jumpei ISHIDA, Minamiashigara-shi (JP)

(73) Assignee: FUJIFILM Corporation, Tokyo (JP)

(21) Appl. No.: 19/401,091

(22) Filed: Nov. 25, 2025

Related U.S. Application Data
(63) Continuation of application No. PCT/JP2024/018251, filed on May 17, 2024.

(30) Foreign Application Priority Data
Jun. 8, 2023 (JP) 2023-094703

(51) Int. Cl. H05K 9/00

(52) U.S. Cl. CPC H05K 9/0088

(57) ABSTRACT

Provided are an electromagnetic wave shielding material having a magnetic layer provided between two metal layers, and an electronic component and an electronic apparatus which include the electromagnetic wave shielding material. A void volume of the electromagnetic wave shielding material is 0.240 mL/mm² or less as a value per 1 mm² of a unit cross-sectional area of the magnetic layer.

### CROSS-REFERENCE TO RELATED APPLICATIONS

This application is a Continuation of PCT International Application No. PCT/JP2024/018251 filed on May 17, 2024, which claims priority under 35 U.S.C. § 119 (a) to Japanese Patent Application No. 2023-094703 filed on Jun. 8, 2023. Each of the above applications is hereby expressly incorporated by reference, in its entirety, into the present application.

### BACKGROUND OF THE INVENTION

### 1. Field of the Invention

The present invention relates to an electromagnetic wave shielding material, an electronic component, and an electronic apparatus.

### 2. Description of the Related Art

In recent years, an electromagnetic wave shielding material has attracted attention as a material for reducing the influence of an electromagnetic wave in various electronic components and various electronic apparatuses (see, for example, WO2022/255023A1).

### SUMMARY OF THE INVENTION

An electromagnetic wave shielding material is capable of exhibiting the performance of shielding electromagnetic waves (hereinafter, also referred to as “electromagnetic wave shielding performance” or “shielding performance”) by reflecting electromagnetic waves incident on the electromagnetic wave shielding material by the electromagnetic wave shielding material and/or by attenuating the electromagnetic waves inside the electromagnetic wave shielding material.

WO2022/255023A1 discloses an electromagnetic wave shielding material having a magnetic layer provided between two metal layers. In paragraph 0027 of WO2022/255023A1, it is described that it is preferable to have a multilayer structure in which a magnetic layer is sandwiched between two metal layers in order to improve shielding performance of the electromagnetic wave shielding material.

As a usage form of the electromagnetic wave shielding material, there may be a usage form in which the electromagnetic wave shielding material is incorporated into an electronic component or an electronic apparatus and then is subjected to a change in humidity and vibration. Therefore, it is desired that the electromagnetic wave shielding material has a small decrease in the shielding performance after being subjected to the change in humidity and the vibration.

In consideration of the above circumstances, an object of an aspect according to the present invention is to provide an electromagnetic wave shielding material having a magnetic layer provided between two metal layers, in which a decrease in electromagnetic wave shielding performance after being subjected to a change in humidity and vibration is suppressed.

An aspect of the present invention is as follows.

[1] An electromagnetic wave shielding material comprising:
a magnetic layer provided between two metal layers,
in which a void volume of the electromagnetic wave shielding material is 0.240 mL/mm² or less as a value per 1 mm² of a unit cross-sectional area of the magnetic layer (hereinafter, also referred to as “cross-sectional void volume”).

[2] The electromagnetic wave shielding material according to [1],
in which the magnetic layer contains magnetic particles and a resin.

[3] The electromagnetic wave shielding material according to [1] or [2],
in which the two metal layers are layers each directly in contact with the magnetic layer.

[4] The electromagnetic wave shielding material according to any one of [1] to [3],
in which both outermost layers are the metal layers.

[5] The electromagnetic wave shielding material according to any one of [1] to [4],
in which the void volume of the electromagnetic wave shielding material is 0.030 mL/mm² or more and 0.240 mL/mm² or less as the value per 1 mm² of the unit cross-sectional area of the magnetic layer.

[6] The electromagnetic wave shielding material according to any one of [1] to [5],
in which the magnetic layer contains magnetic particles and a resin,
the two metal layers are layers each directly in contact with the magnetic layer,
both outermost layers are the metal layers, and
the void volume of the electromagnetic wave shielding material is 0.030 mL/mm² or more and 0.240 mL/mm² or less as the value per 1 mm² of the unit cross-sectional area of the magnetic layer.

[7] An electronic component comprising:
the electromagnetic wave shielding material according to any one of [1] to [6].

[8] An electronic apparatus comprising:
the electromagnetic wave shielding material according to any one of [1] to [6].

According to an aspect of the present invention, it is possible to provide the electromagnetic wave shielding material having the magnetic layer provided between the two metal layers, in which the decrease in the electromagnetic wave shielding performance after being subjected to the change in humidity and the vibration is suppressed. In addition, according to one aspect of the present invention, it is possible to provide an electronic component and an electronic apparatus, which include the electromagnetic wave shielding material.

### DESCRIPTION OF THE PREFERRED EMBODIMENTS

### [Electromagnetic Wave Shielding Material]

One aspect of the present invention relates to an electromagnetic wave shielding material including: a magnetic layer provided between two metal layers, in which a void volume of the electromagnetic wave shielding material is 0.240 mL/mm² or less as a value per 1 mm² of a unit cross-sectional area of the magnetic layer.

In the present invention and the present specification, the “electromagnetic wave shielding material” shall refer to a material that is capable of exhibiting shielding performance against an electromagnetic wave of at least one frequency or at least a part of a range of a frequency band. The “electromagnetic wave” includes a magnetic field wave and an electric field wave. The “electromagnetic wave shielding material” can be a material that is capable of exhibiting shielding performance against one or both of a magnetic field wave of at least one frequency or at least a part of a range of a frequency band and an electric field wave of at least one frequency or at least a part of a range of a frequency band.

### <Cross-Sectional Void Volume>

In the present invention and the present specification, a “cross-sectional void volume” in which the void volume of the electromagnetic wave shielding material is expressed as the value per 1 mm² of the unit cross-sectional area of the magnetic layer is obtained by the following method.

Three sample pieces having a width of 12.5 mm and a length of 25.0 mm are cut out from an electromagnetic wave shielding material to be measured. Each sample piece is cut out from a region within 15.0 mm from at least one end surface of the electromagnetic wave shielding material to be measured. Each sample piece is cut out such that a cross section of the magnetic layer included in the sample piece is exposed at each of four end surfaces of the sample piece. Each sample piece may include or may not include a surface that is an end surface in the electromagnetic wave shielding material to be measured as at least one end surface.

As a measuring device, a measuring device capable of measuring a pore distribution and the like of a measurement sample by mercury porosimetry is used. Specific examples of the measuring device include an Autopore V 9620 pore distribution measuring device manufactured by Micromeritics Instrument Corporation. In the measurement described in the section of Examples described later, the Autopore V 9620 pore distribution measuring device manufactured by Micromeritics Instrument Corporation was used.

The three sample pieces are disposed in a measurement cell so that they do not overlap, and the measurement is performed under a condition of an initial pressure of 4 kilopascal (kPa). 4 kPa is approximately 0.6 psi absolute (psia) in terms of units of psia. By performing the measurement under the condition of the initial pressure of 4 kPa, the pore distribution and the like can be measured for pores having a diameter of up to approximately 320 μm. As the measurement condition, the mercury parameter is set to a mercury contact angle of 130 degrees and a mercury surface tension of 485 dynes/cm.

The total void volume (unit: mL/g) is calculated from the pore distribution in a range of 0.05 to 20 μm obtained by the above-described measurement. The total void volume calculated here is a total of void volumes (unit: mL/g) of the three sample pieces.

A total mass (unit: g) of the three sample pieces is measured by a known method.

The sample void volume (unit: mL) is obtained as “sample void volume=the total void volume×the total mass of three sample pieces”.

A total length of four sides of each of the three sample pieces is “total length of four sides of each sample piece=12.5 mm×2+25.0 mm×2=75 mm”. Therefore, the total length of the four sides of the three sample pieces is 225 mm. In a case where a thickness of the magnetic layer included in the sample piece is denoted by T (unit: mm), a total area of the magnetic layer cross sections (hereinafter, referred to as “magnetic layer exposed end surface”) exposed on the end surfaces of the three sample pieces is “T×225 (unit: mm²)”. The thickness T of the magnetic layer is a total thickness of two or more magnetic layers for the sample piece having two or more magnetic layers.

A cross-sectional void volume (unit: mL/mm²) is calculated by the following expression from the sample void volume (unit: mL) obtained above and the total area (unit: mm²) of the magnetic layer exposed end surfaces of the three sample pieces.

“Cross-sectional void volume=sample void volume/the total area of magnetic layer exposed end surfaces of three sample pieces”

The inventors of the present invention consider that a small value of the cross-sectional void volume obtained by the above-described measuring method means that there are few voids extending from the end surface toward the inside in the magnetic layer of the shielding material. It is considered that, in the electromagnetic wave shielding material having few such voids, moisture absorption and/or dehumidification from the end surface of the magnetic layer of the shielding material is unlikely to occur in a case of being subjected to a change in humidity. It is presumed that this is preferable in suppressing the occurrence of a distribution in a shape and/or physical properties of a region of the magnetic layer of the shielding material from the end surface toward the inside. The inventors of the present invention presume that, in a case where the occurrence of such a distribution can be suppressed, interfacial peeling between the magnetic layer and the metal layer can be suppressed after being subjected to a change in humidity and vibration, and as a result, a significant decrease in shielding performance can be suppressed as compared with before being subjected to a change in humidity and vibration. Note that the present invention is not limited to the supposition described in the present specification.

From the viewpoint of suppressing a decrease in electromagnetic wave shielding performance after being subjected to a change in humidity and vibration, the cross-sectional void volume of the electromagnetic wave shielding material is 0.240 mL/mm² or less, preferably 0.235 mL/mm² or less, and more preferably 0.230 mL/mm² or less, 0.200 mL/mm² or less, 0.150 mL/mm² or less, 0.100 mL/mm² or less, and 0.050 mL/mm² or less in this order. The cross-sectional void volume of the electromagnetic wave shielding material can be, for example, 0.000 mL/mm² or more, more than 0.000 mL/mm², 0.001 mL/mm² or more, 0.010 mL/mm² or more, 0.020 mL/mm² or more, or 0.030 mL/mm² or more. From the viewpoint of further suppressing a decrease in electromagnetic wave shielding performance after being subjected to a change in humidity and vibration, the smaller the value of the cross-sectional void volume of the electromagnetic wave shielding material, the more preferable. The cross-sectional void volume of the electromagnetic wave shielding material can be controlled, for example, by manufacturing conditions of the electromagnetic wave shielding material. This point will be described below in detail.

Hereinafter, the electromagnetic wave shielding material will be described in more detail.

### <Metal Layer>

The electromagnetic wave shielding material has the magnetic layer provided between two metal layers. That is, the electromagnetic wave shielding material has a multilayer structure in which the magnetic layer is sandwiched between two metal layers. The electromagnetic wave shielding material has one or more such multilayer structures and can also include two or more such multilayer structures. That is, the electromagnetic wave shielding material includes at least two metal layers and can also include three or more layers of metal layer, or it includes at least one magnetic layer and can also include two or more magnetic layers. The two or more layers of metal layer included in the electromagnetic wave shielding material have the same composition and thickness in one form and differ in composition and/or thickness in another form. The same applies to a case where the electromagnetic wave shielding material includes two or more magnetic layers, and the same applies to a case where two or more other layers such as a resin layer described later are included in the electromagnetic wave shielding material.

In the present invention and the present specification, the “metal layer” shall refer to a layer containing a metal. The metal layer can be a layer containing one or more kinds of metals as a pure metal consisting of a single metal element, as an alloy of two or more kinds of metal elements, or as an alloy of one or more kinds of metal elements and one or more kinds of non-metal elements.

The metal layer included in the electromagnetic wave shielding material can be a layer that contains one or more kinds of metals selected from the group consisting of various pure metals and various alloys. The metal layer can exhibit an attenuation effect in the shielding material. This point is preferable from the viewpoint of improving the shielding performance of the electromagnetic wave shielding material. Since the attenuation effect increases as the propagation constant increases and the propagation constant increases as the electrical conductivity is higher, it is preferable that the metal layer contains a metal element having a high electrical conductivity. From this point, it is preferable that the metal layer contains, as a main component, a pure metal of Ag, Cu, Au, or Al, or an alloy containing any one of these. The pure metal is a metal consisting of a single metal element and may contain a trace amount of impurities. In general, a metal having a purity of 99.0% or more consisting of a single metal element is called a pure metal. The purity is on a mass basis. The alloy is generally prepared by adding one or more kinds of metal elements or non-metal elements to a pure metal to adjust the composition, for example, in order to prevent corrosion or improve the hardness. The main component in the alloy is a component having the highest ratio on a mass basis, and it can be, for example, a component that occupies 80.0% by mass or more (for example, 99.8% by mass or less) in the alloy. From the viewpoint of economic efficiency, the alloy is preferably an alloy of a pure metal of Cu or Al or an alloy containing Cu or Al as a main component, and from the viewpoint of high electrical conductivity, it is more preferably an alloy of a pure metal of Cu or an alloy containing Cu as a main component.

In one form, the purity of the metal in the metal layer, that is, the content of the metal in the metal layer can be 99.0% by mass or more, 99.5% by mass or more, or 99.8% by mass or more with respect to the total mass of the metal layer. Unless otherwise specified, the content of metal in the metal layer shall refer to the content on a mass basis. For example, as the metal layer, a pure metal or an alloy processed into a sheet shape can be used. For example, as the metal layer, a commercially available metal foil or a metal foil produced by a known method can be used. Regarding a pure metal of Cu, sheets (so-called copper foils) having various thicknesses are commercially available. For example, such a copper foil can be used as the metal layer. The copper foil includes, according to manufacturing methods thereof, an electrolytic copper foil obtained by precipitating a copper foil on a cathode by electroplating and a rolled copper foil obtained by applying heat and pressure to an ingot and stretching the ingot thinly. Any copper foil can be used as the metal layer of the electromagnetic wave shielding material. In addition, for example, regarding Al, sheets (so-called aluminum foils) having various thicknesses are commercially available. For example, such an aluminum foil can be used as the metal layer.

From one or more viewpoints of the viewpoint of economic efficiency, the viewpoint of high electrical conductivity, and the viewpoint of reducing the weight of the electromagnetic wave shielding material, one or both (preferably both) of the two metal layers sandwiching the magnetic layer is preferably a metal layer containing the metal selected from the group consisting of Al, Mg, and Cu, and more preferably a layer containing, as a main component, the metal selected from the group consisting of Al, Mg, and Cu. The main component of the metal layer is a component having the highest ratio on a mass basis. In a layer containing, as a main component, a metal selected from the group consisting of Al, Mg, and Cu, Al, Mg, or Cu is a component having the highest ratio on a mass basis in this layer. Such a layer can contain only one kind of metal or two or three kinds of metals among Al, Mg, and Cu. From the one or more viewpoints, one or both (preferably both) of the two metal layers sandwiching the magnetic layer is preferably a metal layer in which the content of the metal selected from the group consisting of Al, Mg, and Cu is 80.0% by mass or more, and still more preferably a metal layer in which the content of the metal selected from the group consisting of Al, Mg, and Cu is 90.0% by mass or more. The metal layer containing at least Al among Al, Mg, and Cu can be a metal layer in which the Al content is 80.0% by mass or more, and it can be a metal layer in which the Al content is 90.0% by mass or more. The metal layer containing at least Mg among Al, Mg, and Cu can be a metal layer in which the Mg content is 80.0% by mass or more, and it can be a metal layer in which the Mg content is 90.0% by mass or more. The metal layer containing at least Cu among Al, Mg, and Cu can be a metal layer in which the Cu content is 80.0% by mass or more, and it can be a metal layer in which the Cu content is 90.0% by mass or more. The content of the metal selected from the group consisting of Al, Mg, and Cu, the Al content, the Mg content, and the Cu content can be each, for example, 100% by mass or less or 99.9% by mass or less. The content of the metal selected from the group consisting of Al, Mg, and Cu, the Al content, the Mg content, and the Cu content are each the content with respect to the total mass of the metal layer.

From the viewpoint of further improving the processability of the metal layer and the shielding performance of the electromagnetic wave shielding material, the thickness of the metal layer in terms of the thickness per one layer is preferably 4 μm or more, more preferably 5 μm or more, and still more preferably 10 μm or more. On the other hand, from the viewpoint of the processability of the metal layer, the thickness of the metal layer in terms of the thickness per one layer is preferably 200 μm or less, more preferably 100 μm or less, and still more preferably 50 μm or less. In the electromagnetic wave shielding material, the thicknesses of the plurality of metal layers can be the same thickness or thicknesses different from each other.

In one form, one or both of the outermost layers can be a metal layer in the electromagnetic wave shielding material. This point can contribute to the fact that the electromagnetic wave shielding material can exhibit high shielding performance against a magnetic field wave in a low frequency region of about 100 kHz to 1 MHz. In addition, the fact that at least one of the outermost layers of the electromagnetic wave shielding material is a metal layer can contribute to suppressing edge peeling in a formed article obtained by forming processing. In one form, one or both of the outermost layers of the electromagnetic wave shielding material can be a metal layer that sandwiches a magnetic layer together with another metal layer.

### <Magnetic Layer>

### (Magnetic Material)

In the present invention and the present specification, “magnetic” means having a ferromagnetic property. The magnetic layer can contain a magnetic material, and examples of the magnetic material include magnetic particles. As the magnetic particle, one kind selected from the group consisting of magnetic particles generally called soft magnetic particles, such as metal particles and ferrite particles, can be used, or two or more kinds therefrom can be used in combination at any ratio.

### Metal Particle

Since the metal particles generally have a saturation magnetic flux density of about 2 to 3 times as compared with ferrite particles, the metal particles can maintain specific magnetic permeability and exhibit shielding performance even under a strong magnetic field without magnetic saturation. Therefore, the magnetic particles to be contained in the magnetic layer are preferably metal particles. In the present invention and the present specification, a layer containing metal particles as the magnetic material shall correspond to the “magnetic layer”.

Examples of the metal particles include particles of Sendust (a Fe—Si—Al alloy), permalloy (a Fe—Ni alloy), molybdenum permalloy (a Fe—Ni—Mo alloy), a Fe—Si alloy, a Fe—Cr alloy, a Fe-containing alloy generally called the iron-based amorphous alloy, a Co-containing alloy generally called the cobalt-based amorphous alloy, an alloy generally called the nanocrystal alloy, iron, Permendur (a Fe—Co alloy). Among them, Sendust is preferable since it exhibits a high saturation magnetic flux density and a high specific magnetic permeability. The metal particle may contain, in addition to the constitutional element of the metal (including the alloy), elements contained in an additive that can be optionally added and/or elements contained in impurities that can be unintentionally mixed in a manufacturing process of the metal particle at any content rate. In the metal particle, the content of the constitutional element of the metal (including the alloy) is preferably 90.0% by mass or more and more preferably 95.0% by mass or more, and it may be 100% by mass or may be less than 100% by mass, 99.9% by mass or less, or 99.0% by mass or less.

In one form, a magnetic layer that exhibits a high magnetic permeability (specifically, a real part of a complex specific magnetic permeability) is preferable. In a case where a complex specific magnetic permeability is measured by a magnetic permeability measuring apparatus, a real part u′ and an imaginary part u″ are generally displayed. In the present invention and the present specification, a real part of a complex specific magnetic permeability shall refer to such a real part u′. Hereinafter, a real part of a complex specific magnetic permeability at a frequency of 100 kHz is also simply referred to as “magnetic permeability”. The magnetic permeability can be measured by a commercially available magnetic permeability measuring apparatus or a magnetic permeability measuring apparatus having a known configuration. From the viewpoint that the electromagnetic wave shielding material can exhibit still more excellent shielding performance, the magnetic layer having a magnetic permeability (the real part of the complex specific magnetic permeability at a frequency of 100 kHz) of 30 or more is preferable. The magnetic permeability thereof is more preferably 40 or more, still more preferably 50 or more, still more preferably 60 or more, still more preferably 70 or more, even more preferably 80 or more, even still more preferably 90 or more, and even further still more preferably 100 or more. In addition, the magnetic permeability can be, for example, 200 or less, 190 or less, 180 or less, 170 or less, or 160 or less, and it can exceed the values exemplified here. From the viewpoint of further improving the shielding performance of the electromagnetic wave shielding material, the higher the magnetic permeability, the more preferable. The magnetic permeability can be, for example, a value measured at a measurement temperature of 25° C.

### Average Particle Size

In a case where the magnetic layer contains magnetic particles, an average particle size of the magnetic particles can be, for example, 5 μm or more, and can be 10 μm or more, 15 μm or more, or 20 μm or more. The average particle size of the magnetic particles is, for example, preferably 150 μm or less, and more preferably 140 μm or less, 130 μm or less, 120 μm or less, 110 μm or less, 100 μm or less, 90 μm or less, 80 μm or less, 70 μm or less, 60 μm or less, and 50 μm or less in this order.

In the present invention and the present specification, average particle sizes of various powders are values measured by the following method using a transmission electron microscope, unless otherwise noted. The “powder” refers to an aggregate of a plurality of particles. The aggregate of the plurality of particles not only includes an aspect in which particles constituting the aggregate directly come into contact with each other, but also includes an aspect in which one or more of other components are interposed between the particles. The term “particle” is used to describe a powder in some cases.

The powder is imaged at an imaging magnification of 100,000 with a transmission electron microscope, and the image is printed on printing paper, is displayed on a display, or the like so that the total magnification ratio is 500,000 to obtain an image of particles configuring the powder. A target particle is selected from the obtained image of particles, a contour of the particle is traced by a digitizer, and a size of the particle (primary particle) is measured. The primary particles are independent particles without aggregation.

The measurement described above is performed regarding 500 particles randomly extracted. An arithmetic average of the particle sizes of 500 particles thus obtained is an average particle size. As the transmission electron microscope, a transmission electron microscope H-9000 manufactured by Hitachi, Ltd. can be used, for example. In addition, the measurement of the particle size can be performed by well-known image analysis software, for example, image analysis software KS-400 manufactured by Carl Zeiss.

In the present invention and the present specification, unless otherwise noted, the size of the primary particles configuring the powder is defined as follows.
(1) in a case where the shape of the particle observed in the particle image described above is a needle shape, a fusiform shape, or a columnar shape (here, a height is greater than a maximum major diameter of a bottom surface), the size of the primary particles configuring the powder is shown as a length of a long axis configuring the particle, that is, a long axis length,
(2) in a case where the shape of the particle is a plate shape or a columnar shape (here, a thickness or a height is smaller than a maximum major diameter of a plate surface or a bottom surface), the size of the primary particles is shown as a maximum major diameter of the plate surface or the bottom surface, and
(3) in a case where the shape of the particle is a sphere shape, a polyhedron shape, or an amorphous shape, and the long axis configuring the particles cannot be specified from the shape, the size of the primary particles is shown as an equivalent circle diameter. The equivalent circle diameter refers to a value obtained by a circle projection method.

The average particle size of the magnetic particles contained in the magnetic layer can be obtained, for example, by performing the above-described measurement on the magnetic particles used for producing the magnetic layer or on the magnetic particles of the same lot as the magnetic particles. In addition, for example, by extracting the magnetic particles from the magnetic layer by a known method and performing the above-described measurement on the extracted magnetic particles, the average particle size of the magnetic particles contained in the magnetic layer can be obtained.

The content of the magnetic particles in the magnetic layer can be, for example, 50% by mass or more, 60% by mass or more, 70% by mass or more, and 80% by mass or more with respect to the total mass of the magnetic layer, and it can be, for example, 100% by mass or less, 98% by mass or less, or 95% by mass or less.

In one form, as the magnetic layer, a sintered body (a ferrite plate) of ferrite particles or the like can be used. Considering that, for example, there is a case where the electromagnetic wave shielding material is cut out to a desired size and there is a case where the electromagnetic wave shielding material is bent into a desired shape, the magnetic layer is preferably a layer that contains a resin as compared with a ferrite plate which is a sintered body.

In one form, the magnetic layer can be a layer having insulating properties. In the present invention and the present specification, the “insulating properties” means that the electrical conductivity is smaller than 1 siemens(S)/m. The electrical conductivity of a certain layer is calculated according to the following expression from the surface electrical resistivity of the layer and the thickness of the layer. The electrical conductivity can be measured by a known method.

$$Electrical conductivity [ S / m ] = 1 / ( surface electrical resisitivity [ Ω ] \times thickness [ m ] )$$

The inventors of the present invention presume that it is preferable that the magnetic layer is a layer having insulating properties in order for the electromagnetic wave shielding material to exhibit higher shielding performance. From this point, the electrical conductivity of the magnetic layer is preferably smaller than 1 S/m, more preferably 0.5 S/m or less, still more preferably 0.1 S/m or less, and even still more preferably 0.05 S/m or less. The electrical conductivity of the magnetic layer can be, for example, 1.0×10⁻¹² S/m or more or 1.0×10⁻¹⁰ S/m or more. (Resin)

The magnetic layer can be a layer containing a resin, and it can be a layer containing a magnetic material (for example, magnetic particles) and a resin. In the present invention and the present specification, the “resin” means a polymer, and it shall include rubber and an elastomer as well. The polymer includes a homopolymer and a copolymer. The rubber includes natural rubber and synthetic rubber. The elastomer is a polymer that exhibits elastic deformation. In the present invention and the present specification, a layer containing both magnetic material and a resin shall correspond to the “magnetic layer”. In the magnetic layer containing the magnetic material and the resin, the content of the resin can be, for example, 1 part by mass or more, 3 parts by mass or more, or 5 parts by mass or more per 100 parts by mass of the magnetic material, and it can be 20 parts by mass or less or 15 parts by mass or less.

The resin can act as a binder in the magnetic layer. Examples of the resin to be contained in the magnetic layer include known thermoplastic resins in the related art, a thermosetting resin, an ultraviolet curable resin, a radiation curable resin, a rubber-based material, and an elastomer. Specific examples thereof include a polyester resin, a polyethylene resin, a polyvinyl chloride resin, a polyvinyl butyral resin, a polyurethane resin, a polyester urethane resin, a cellulose resin, an acrylonitrile-butadiene-styrene (ABS) resin, a nitrile-butadiene rubber, a styrene-butadiene rubber, an epoxy resin, a phenol resin, an amide resin, a silicone resin, a styrene-based elastomer, an olefin-based elastomer, a vinyl chloride-based elastomer, a polyester-based elastomer, a polyamide-based elastomer, a polyurethane-based elastomer, and an acrylic elastomer.

In addition to the above-described components, the magnetic layer can also contain any amount of one or more known additives such as a curing agent, a dispersing agent, a stabilizer, and a coupling agent.

In a case where the electromagnetic wave shielding material includes only one magnetic layer, the thickness of this one magnetic layer can be, for example, 5 μm or more, and it is preferably 10 μm or more and more preferably 20 μm or more from the viewpoint of further improving the shielding performance of the electromagnetic wave shielding material. Meanwhile, the thickness of this one magnetic layer can be, for example, 100 μm or less or 90 μm or less, and it is preferably less than 90 μm, more preferably 80 μm or less, and still more preferably 70 μm or less, from the viewpoint of improving forming workability of the electromagnetic wave shielding material.

In a case where the electromagnetic wave shielding material includes two or more magnetic layers, the thickness of each of the two or more magnetic layers (that is, the thickness per one layer) can be, for example, 5 μm or more, and it is preferably 10 μm or more and more preferably 20 μm or more from the viewpoint of further improving the shielding performance of the electromagnetic wave shielding material. Meanwhile, the thickness of each of the two or more magnetic layers can be, for example, 100 μm or less or 90 μm or less, and it is preferably less than 90 μm and more preferably 80 μm or less. The respective thicknesses of the two or more magnetic layers can be the same thickness or thicknesses different from each other.

The thickness of each layer included in the electromagnetic wave shielding material shall be determined by imaging a cross section exposed by a known method with a scanning electron microscope (SEM) and determining an arithmetic average of thicknesses of five randomly selected points in the obtained SEM image.

In one form, in the multilayer structure in which the magnetic layer is sandwiched between the two metal layers, one or both of the two metal layers and the magnetic layer can be disposed as layers directly in contact with each other. That is, one or both of the two metal layers and the magnetic layer can be adjacent to each other without interposing another layer.

In addition, in one form, a multilayer structure in which the magnetic layer is sandwiched between the two metal layers can also include one or more layers containing a resin, provided between one or both of the two metal layers and the magnetic layer. The layer containing a resin is a layer containing one or more kinds of resins. In the electromagnetic wave shielding material, the thickness of the layer containing a resin (in a case where a plurality of layers containing a resin are included, the total thickness thereof) can be, for example, 1 μm or more and 200 μm or less or 1 μm or more and 150 μm or less. Hereinafter, a specific form of the layer containing a resin will be described.

### <Layer Containing Resin>

### (Pressure-Sensitive Adhesive Layer)

A pressure-sensitive adhesive layer can be mentioned as one form of the layer containing a resin. In the present invention and the present specification, the “pressure-sensitive adhesive layer” refers to a layer having tackiness on a surface at normal temperature. Regarding the tackiness, the “normal temperature” shall be defined as 23° C. In a case where such a layer comes into contact with an adherend, the layer adheres to the adherend due to the adhesive force thereof. In general, the tackiness is the property of exhibiting an adhesive force in a short time after coming into contact with an adherend with a very light force, and in the present invention and the present specification, the above-described “having tackiness” refers to that the result is No. 1 to No. 32 in a tilted ball tack test (measurement environment: a temperature of 23° C. and a relative humidity of 50%) specified in JIS Z 0237:2009. In a case where another layer is laminated on the surface of the pressure-sensitive adhesive layer, the surface of the pressure-sensitive adhesive layer exposed, for example, by peeling off the other layer can be subjected to the above-described test. In a case where another layer is laminated on each of one surface and the other surface of the pressure-sensitive adhesive layer, the layer on the side of either surface may be peeled off.

As the pressure-sensitive adhesive layer, it is possible to use those obtained by applying a composition for forming a pressure-sensitive adhesive layer containing a pressure sensitive adhesive such as an acrylic pressure sensitive adhesive, a rubber-based pressure-sensitive adhesive, a silicone-based pressure-sensitive adhesive, or a urethane-based pressure-sensitive adhesive and processing it into a film shape.

The composition for forming a pressure-sensitive adhesive layer can be applied onto, for example, a support. The coating can be carried out using a known coating device such as a blade coater or a die coater. The coating can be carried out by a so-called roll-to-roll method or a batch method.

Examples of the support onto which the composition for forming a pressure-sensitive adhesive layer is applied include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide. As the support, it is possible to use a support in which a surface (a surface to be coated) onto which the composition for forming a pressure-sensitive adhesive layer is applied is subjected to a peeling treatment according to a known method. One form of the peeling treatment includes forming a release layer. In addition, a commercially available peeling-treated resin film can also be used as the support. In a case of using a support in which the surface to be coated is subjected to the peeling treatment, it is possible to easily separate the pressure-sensitive adhesive layer and the support after the film formation.

By applying a composition for forming a pressure-sensitive adhesive layer, in which a pressure sensitive adhesive is dissolved and/or dispersed in a solvent, onto the surface to be coated and carrying out drying, a pressure-sensitive adhesive layer can be formed. Alternatively, a pressure sensitive adhesive tape including a pressure-sensitive adhesive layer can also be used. As the pressure sensitive adhesive tape, for example, it is possible to use a double-sided tape. The double-sided tape has pressure-sensitive adhesive layers on both sides of the support. In addition, as the pressure sensitive adhesive tape, it is possible to use a pressure sensitive adhesive tape having a pressure-sensitive adhesive layer on one surface of a support. Examples of the support include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide, a non-woven fabric, and paper. As the pressure sensitive adhesive tape having a pressure-sensitive adhesive layer on one surface or both surfaces of a support, it is possible to use a commercially available product, or it is possible to use a pressure sensitive adhesive tape produced by a known method.

The thickness of the pressure-sensitive adhesive layer is not particularly limited, and the thickness per layer can be, for example, 1 μm or more and 30 μm or less.

### (Adhesive Layer)

An adhesive layer can also be mentioned as one form of the layer containing a resin. In the present invention and the present specification, the “adhesive layer” is a layer in which a liquid or gel-like adhesive is solidified after coming into contact with an adherend and undergoing a state change such as drying or curing, at that time, adhesiveness to the adherend is exhibited by an anchoring effect, a physical interaction, or formation of a chemical bond to the adherend. In one form, the adhesive layer can be a layer having no tackiness on the surface at normal temperature.

The adhesive contains a resin that is solidified after being dried or cured. Examples of such a resin include a vinyl acetate resin, an ethylene vinyl acetate resin, an epoxy resin, a cyanoacrylate resin, an acrylic resin, a polyurethane resin, a chloroprene rubber, and a styrene butadiene rubber. These resins may be in the form of a liquid or a gel in the resin itself. Alternatively, the solid resin may be dissolved in a solvent to be in a liquid or gel form. Examples of the solvent contained in the adhesive include water, ketone-based solvents such as acetone, methyl ethyl ketone, and cyclohexanone, acetic acid ester-based solvents such as ethyl acetate, butyl acetate, cellosolve acetate, propylene glycol monomethyl ether acetate, and carbitol acetate, carbitols such as cellosolve and butyl carbitol, aromatic hydrocarbon-based solvents such as toluene and xylene, and amide-based solvents such as dimethylformamide, dimethylacetamide, and N-methylpyrrolidone, alcohol-based solvents such as ethanol, methanol, and propanol, and halogen-based solvents such as dichloromethane, trichloroethylene, and dichlorofluoroethane.

The thickness of the adhesive layer is not particularly limited, and the thickness per layer can be, for example, 1 μm or more and 30 μm or less.

### (Resin Layer)

A resin layer can also be mentioned as one form of the layer containing a resin. In the present invention and the present specification, the “resin layer” is a resin film obtained by forming a thermoplastic resin such as a synthetic resin into a film shape, and the resin film has a film-like structure by itself and does not have tackiness at normal temperature.

Examples of the thermoplastic resin contained in the resin film include various resins such as a polyethylene (PE) resin, a polypropylene (PP) resin, a polyvinyl chloride (PVC) resin, a polystyrene (PS) resin, a vinyl acetate resin, a polyurethane resin, a polyvinyl alcohol resin, an ethylene vinyl acetate resin, styrene butadiene rubber, acrylonitrile butadiene rubber, silicone rubber, an olefin-based elastomer (PP), a styrene-based elastomer, an acrylonitrile-butadiene-styrene (ABS) resin, polyethylene terephthalate (PET), a polyester resin such as polyethylene naphthalate (PEN), a polycarbonate (PC) resin, an acrylic resin such as polymethyl methacrylate (PMMA), cyclic polyolefin, and triacetyl cellulose (TAC).

The resin layer can be bonded to a metal layer or a magnetic layer by interposing a pressure-sensitive adhesive layer or an adhesive layer. In addition, since the resin layer is a layer containing a thermoplastic resin, the resin layer has the property of being softened by heating and flows and follows minute protrusions and recessions on the surface of the adherend by being pressed against the adherend in a state of being heated, thereby capable of exhibiting an adhesive force due to the anchoring effect, and then it is cooled, whereby the adhered state can be maintained. Therefore, in one form, the resin layer and the other layer can be bonded to each other without interposing the pressure-sensitive adhesive layer or the adhesive layer.

The thickness of the resin layer in terms of the thickness per one resin layer is preferably 10 μm or greater and more preferably 12 μm or greater. The thickness of the resin layer in terms of the thickness per one resin layer is preferably 250 μm or less, more preferably 230 μm or less, still more preferably 210 μm or less, and even still more preferably 190 μm or less. In one form, the electromagnetic wave shielding material can include, in a multilayer structure in which the magnetic layer is sandwiched between the two metal layers, one or more resin layers having a thickness in the above range between one or both of the two metal layers and the magnetic layer. For example, the multilayer structure can include one magnetic layer having a thickness in the above range between one metal layer of the two metal layers and the magnetic layer and/or between the other metal layer and the magnetic layer.

### <Specific Example of Layer Configuration>

In a case where the electromagnetic wave shielding material having a multilayer structure in which the magnetic layer is sandwiched between the two metal layers includes only one magnetic layer, this one magnetic layer is a magnetic layer sandwiched between the two metal layers.

In a case where the electromagnetic wave shielding material having a multilayer structure includes two or more magnetic layers, at least one layer of these two or more magnetic layers is a magnetic layer sandwiched between the two metal layers. Specifically, all or only a part of the magnetic layers included in the electromagnetic wave shielding material having a multilayer structure is a magnetic layer sandwiched between the two metal layers.

In one form, in a multilayer structure in which the magnetic layer is sandwiched between two metal layers, the magnetic layer can be in direct contact with both metal layers. In this case, specific examples of the layer configuration of the electromagnetic wave shielding material include the following examples.
Example A1: “Metal layer/magnetic layer/metal layer”
Example A2: “Metal layer/magnetic layer/metal layer/magnetic layer/metal layer”
Example A3: “Metal layer/magnetic layer/metal layer/magnetic layer/metal layer/magnetic layer/metal layer”

In an electromagnetic wave shielding material having two or more multilayer structures that include the magnetic layer between two metal layers, for example, as in Example A2 and Example A3, a metal layer that sandwiches a magnetic layer in a certain multilayer structure can also be a metal layer that sandwiches a magnetic layer in another multilayer structure. In the electromagnetic wave shielding material, the total number of multilayer structures including the magnetic layer between two metal layers can be, for example, 1 to 4. The total number of the multilayer structures is one in Example A1, two in Example A2, and three in Example A3. It is preferable that the total number of the multilayer structures is two or more (for example, two, three, or four) from the viewpoint of further improving the shielding performance of the electromagnetic wave shielding material. In the above, the symbol “/” means that the layer described on the left side of this symbol and the layer described on the right side of this symbol are in direct contact with each other without another layer being interposed therebetween. This point is also the same in the following description unless otherwise noted.

In another form, a multilayer structure in which the magnetic layer is sandwiched between the two metal layers of the electromagnetic wave shielding material can include one or more layers containing a resin between one or both of the two metal layers and the magnetic layer. In the above-described multilayer structure, one of the two metal layers may be adjacent to the magnetic layer without interposing another layer, and one or more layers containing a resin may be included between the other metal layer and the magnetic layer. In addition, the multilayer structure may include one or more layers containing a resin, provided between each of the two metal layers and the magnetic layer. The layer containing a resin, which is located between the metal layer and the magnetic layer, is preferably at least a resin layer. In one form, the electromagnetic wave shielding material can include one or more layers containing a polyester resin between one or both of the two metal layers and the magnetic layer, and the layer containing a polyester resin is preferably a resin layer.

The multilayer structure can include a pressure-sensitive adhesive layer and/or an adhesive layer between the resin layer and the metal layer. In one form, in the multilayer structure, the pressure-sensitive adhesive layer and/or the adhesive layer may be included between the resin layer and the magnetic layer. In another form, in the multilayer structure, the resin layer and the magnetic layer can be in direct contact with each other. That is, the resin layer and the magnetic layer can be adjacent to each other without interposing another layer.

The electromagnetic wave shielding material can include, for example, a total of 1 to 12 layers containing a resin. The total number of layers of resin layers (preferably the resin layers having the thickness described above) included in the electromagnetic wave shielding material can be, for example, one to four layers. The total number of layers of layers selected from the group consisting of the pressure-sensitive adhesive layer and the adhesive layer, which are included in the electromagnetic wave shielding material, can be, for example, one to four layers or one to eight layers.

Examples of the disposition of the “magnetic layer”, the “metal layer”, the “resin layer”, and the “pressure-sensitive adhesive layer or adhesive layer” in the electromagnetic wave shielding material include the following examples. In the following examples, the “pressure-sensitive adhesive layer” may include a support, and the “pressure-sensitive adhesive layer” may be a pressure sensitive adhesive tape having a pressure-sensitive adhesive layer on one or both surfaces of the support. For example, as in Example B3, metal layers that sandwich a certain magnetic layer can be metal layers that sandwich another magnetic layer. For example, in Example B3, the metal layer 2 is one of the two metal layers that sandwich the magnetic layer 1, and it is also one of the two metal layers that sandwich the magnetic layer 2. In addition, in Example B3, one of the outermost layers of the electromagnetic wave shielding material is the metal layer 1 that sandwiches the magnetic layer 1 together with the metal layer 2, and the other of the outermost layers of the electromagnetic wave shielding material is the metal layer 3 that sandwiches the magnetic layer 2 together with the metal layer 2.

Example B1: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2”

Example B2: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2”

Example B3: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2/pressure-sensitive adhesive layer 3 or adhesive layer 3/resin layer 3/magnetic layer 2/resin layer 4/pressure-sensitive adhesive layer 4 or adhesive layer 4/metal layer 3”

Example B4: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2/magnetic layer 2/resin layer 3/pressure-sensitive adhesive layer 3 or adhesive layer 3/metal layer 3”

Example B5: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2/magnetic layer 2/metal layer 3/pressure-sensitive adhesive layer 3 or adhesive layer 3/resin layer 3”

Example B6: “Metal layer 1/pressure-sensitive adhesive layer 1 or adhesive layer 1/resin layer 1/magnetic layer 1/metal layer 2/magnetic layer 2/resin layer 2/pressure-sensitive adhesive layer 2 or adhesive layer 2/metal layer 3”

Example B7: “Metal layer 1/pressure-sensitive adhesive layer 1 or adhesive layer 1/resin layer 1/magnetic layer 1/resin layer 2/magnetic layer 2/metal layer 3/pressure-sensitive adhesive layer 2 or adhesive layer 2/resin layer 2”

Example B8: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2/magnetic layer 2/resin layer 3/pressure-sensitive adhesive layer 3 or adhesive layer 3/metal layer 3”

Example B9: “Resin layer 1/pressure-sensitive adhesive layer 1 or adhesive layer 1/metal layer 1/magnetic layer 1/metal layer 2/pressure-sensitive adhesive layer 2 or adhesive layer 2/resin layer 2”

### <Manufacturing Method for Electromagnetic Wave Shielding Material>

### (Film Forming Method for Magnetic Layer)

The magnetic layer can be produced, for example, by drying a coating layer that is provided by applying a composition for forming a magnetic layer. The composition for forming a magnetic layer can contain the components described above and can further contain one or more kinds of solvents. Examples of the solvent include various organic solvents, for example, ketone-based solvents such as acetone, methyl ethyl ketone, and cyclohexanone, acetic acid ester-based solvents such as ethyl acetate, butyl acetate, cellosolve acetate, propylene glycol monomethyl ether acetate, and carbitol acetate, carbitols such as cellosolve and butyl carbitol, aromatic hydrocarbon-based solvents such as toluene and xylene, and amide-based solvents such as dimethylformamide, dimethylacetamide, and N-methylpyrrolidone. One kind of solvent or two or more kinds of solvents selected in consideration of the solubility of the component that is used in the preparation of the composition for forming a magnetic layer can be mixed at any ratio and used. The solvent content of the composition for forming a magnetic layer is not particularly limited and may be determined in consideration of the coatability of the composition for forming a magnetic layer.

The composition for forming a magnetic layer can be prepared by sequentially mixing various components in any order or simultaneously mixing them. In addition, as necessary, a dispersion treatment can be carried out using a known dispersing machine such as a ball mill, a bead mill, a sand mill, or a roll mill, and/or a stirring treatment can be also carried out using a known stirrer such as a shaking type stirrer.

The composition for forming a magnetic layer can be applied onto, for example, a support. The coating can be carried out using a known coating device such as a blade coater or a die coater. The coating can be carried out by a so-called roll-to-roll method or a batch method. A coating speed in a case of performing coating is not particularly limited.

Examples of the support onto which the composition for forming a magnetic layer is applied include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide. For these resin films, reference can be made to paragraphs 0081 to 0086 of JP2015-187260A. As the support, it is possible to use a support in which a surface (a surface to be coated) onto which the composition for forming a magnetic layer is applied is subjected to a peeling treatment according to a known method. One form of the peeling treatment includes forming a release layer. For the release layer, reference can be made to paragraph 0084 of JP2015-187260A. In addition, a commercially available peeling-treated resin film can also be used as the support. In a case of using a support in which the surface to be coated is subjected to the peeling treatment, it is possible to easily separate the magnetic layer and the support after the film formation.

A coating layer formed by applying the composition for forming a magnetic layer can be subjected to a drying treatment according to a known method such as heating or hot air blowing. In order to obtain the electromagnetic wave shielding material having a small value of the cross-sectional void volume, it is preferable to suppress the rapid drying in the initial drying of the coating layer of the composition for forming a magnetic layer. For example, as a specific example of the means for suppressing the rapid drying in the initial drying of the coating layer of the composition for forming a magnetic layer, it is possible to exemplify performing the drying treatment of the coating layer of the composition for forming a magnetic layer in two or more stages, and setting an atmospheric temperature in a drying treatment in an initial stage such as a first stage to a relatively low temperature and/or adjusting a solvent gas concentration in an atmosphere in which the drying treatment is performed to a relatively high concentration. The solvent gas in the atmosphere in which the drying treatment is performed can be a gas of a solvent that volatilizes from the coating layer formed by applying the composition for forming a magnetic layer. Therefore, examples of the solvent gas include a gas of a solvent contained in the composition for forming a magnetic layer. The solvent gas concentration in the atmosphere in which the drying treatment is performed can be controlled, for example, by adjusting a mixing ratio of air in the atmosphere and the solvent gas volatilized from the coating layer by appropriately changing an amount of air (for example, heated air) newly taken into the atmosphere (for example, atmosphere in a drying device) in which the drying treatment is performed. The drying treatment in the initial stage can be performed, for example, for 1 minute or longer and 5 minutes or shorter in an atmosphere having an atmospheric temperature of 50° C. or higher and 100° C. or lower and a solvent gas concentration of 0.1% by volume or higher and 0.8% by volume or lower. The drying treatment after the drying treatment in the initial stage can be performed, for example, for 1 minute or longer and 2 hours or shorter in an atmosphere having a solvent gas concentration lower than that in the drying treatment in the initial stage and an atmospheric temperature of 80° C. or higher and 150° C. or lower. The time related to the drying treatment refers to a time required for any position of the coating layer to enter and exit the drying treatment zone of the drying device in a case where the coating layer of the composition for forming a magnetic layer is continuously transported to the drying treatment zone to perform the drying treatment.

### (Pressurization Treatment of Magnetic Layer)

The magnetic layer can also be subjected to a pressurization treatment after film formation. In a case of subjecting the magnetic layer containing the magnetic particles to a pressurization treatment, it is possible to increase the density of the magnetic particles in the magnetic layer, and it is possible to obtain a higher magnetic permeability.

The pressurization treatment can be carried out by applying pressure in the thickness direction of the magnetic layer using a plate-shape pressing machine, a roll pressing machine, or the like. In the plate-shape pressing machine, an object to be pressurized can be disposed between two flat press plates that are disposed vertically, and the two press plates can be put together by mechanical or hydraulic pressure to apply pressure to the object to be pressurized. In the roll pressing machine, an object to be pressurized is allowed to pass between the rotating pressurization rolls that are disposed vertically, and at that time, mechanical or hydraulic pressure is applied to the pressurization rolls, or the distance between the pressurization rolls is made to be smaller than the thickness of the object to be pressurized, whereby the pressure can be applied.

The pressure during the pressurization treatment can be set freely. For example, in a case of a plate-shape pressing machine, it is, for example, 1 to 50 newtons (N)/mm². In a case of a roll pressing machine, it is, for example, 20 to 400 N/mm in terms of the linear pressure. Increasing the pressure during the pressurization treatment may reduce a value of a cross-sectional void volume of the electromagnetic wave shielding material to be formed.

The pressurization time can be set freely. It takes, for example, 5 seconds to 30 minutes in a case where a plate-shape pressing machine is used. In a case where a roll pressing machine is used, the pressurization time can be controlled by the transport speed of the object to be pressurized, where the transport speed is, for example, 10 cm/min to 200 m/min.

The materials of the press plate and the pressurization roll can be randomly selected from metal, ceramics, plastic, and rubber.

In the pressurization treatment, it is also possible to carry out a pressurization treatment by applying a temperature to both of upper and lower press plates of a plate-shape pressing machine or one press plate thereof, or one roll of upper and lower rolls of a roll pressing machine. The magnetic layer can be softened by heating, which makes it possible to obtain a high compression effect in a case where pressure is applied. The temperature at the time of heating can be set freely, and it is, for example, 50° C. or higher and 200° C. or lower. The temperature at the time of heating can be the internal temperature of the press plate or the roll. Such a temperature can be measured with a thermometer installed inside the press plate or the roll.

After the heating and pressurization treatment with the plate-shape pressing machine, the press plates can be spaced apart from each other, for example, in a state where the temperature of the press plates is high, whereby the magnetic layer can be taken out. Alternatively, the press plate can be cooled by a method such as water cooling or air cooling while maintaining the pressure, and then the press plates can be spaced apart to take out the magnetic layer.

In the roll pressing machine, the magnetic layer can be cooled immediately after pressing, by a method such as water cooling or air cooling.

It is also possible to repeat the pressurization treatment two or more times.

In a case where the magnetic layer is formed into a film on a release film, it is possible to carry out a pressurization treatment, for example, in a state where the magnetic layer is laminated on the release film. Alternatively, the magnetic layer can also be peeled off from the release film and can be subjected to a pressurization treatment as a single layer of the magnetic layer.

### (Bonding of Various Layers)

A pressure-sensitive adhesive layer or an adhesive layer can be used for bonding various layers. The pressure-sensitive adhesive layer and the adhesive layer are as described above.

In addition, in the electromagnetic wave shielding material, two layers adjacent to each other can be also adhered to each other, for example, by applying pressure and heat to carry out crimping. A plate-shape pressing machine, a roll pressing machine, or the like can be used for the crimping. For example, in a case where the magnetic layer is disposed as a layer that is in direct contact with the adjacent layer, the magnetic layer is softened in a crimping step, and the contact with the surface of the adjacent layer is promoted, whereby the magnetic layer and the adjacent layer can be bonded to each other without interposing another layer. The pressure at the time of crimping can be set freely. It is, for example, 1 to 50 N/mm² in a case of a plate-shape pressing machine. In a case of a roll pressing machine, it is, for example, 20 to 400 N/mm in terms of the linear pressure. The pressurization time at the time of crimping can be set freely. It takes, for example, 5 seconds to 30 minutes in a case where a plate-shape pressing machine is used. In a case where a roll pressing machine is used, the pressurization time can be controlled by a transport speed of an object to be pressurized, and the transport speed is, for example, 10 cm/min to 200 m/min. The temperature at the time of crimping can be selected freely, and it is, for example, 20° C. or higher and 200° C. or lower. The temperature at the time of crimping can be, for example, the internal temperature of the press plate or the roll.

The electromagnetic wave shielding material can be incorporated into, in any shape, an electronic component or an electronic apparatus. The electromagnetic wave shielding material can have a sheet shape, where the size thereof is not particularly limited. In the present invention and the present specification, the “sheet” has the same meaning as the “film”. In addition, the electromagnetic wave shielding material can be a three-dimensionally formed article obtained by three-dimensionally forming a sheet-shaped electromagnetic wave shielding material, or it can also be a sheet-shaped electromagnetic wave shielding material for three-dimensional forming. As a three-dimensional forming method, it is possible to use various forming methods such as mold press forming, vacuum forming, and air pressure forming. Regarding the forming method, for example, the forming that is carried out without heating a forming target and/or a mold or carried out by heating a forming target and/or a mold without raising the temperature too much is generally called cold forming. Examples of the cold forming method include draw forming and bulge forming. The draw forming is a forming method in which a sheet-shaped forming target is pressed using a pair of molds of a female die and a male die, thereby being formed into bottomed containers having various shapes such as a cylinder, a square cylinder, and a conical shape. In contrast, a method of forming a formed article having a shape in which a curved surface protrudes from a flat surface, from a sheet-shaped forming target is bulge forming. The bulge forming can be carried out by pressing with only a male die without a female die. The draw forming is roughly classified into deep draw forming and shallow draw forming. A formed article having a shallow depth is formed by the shallow draw forming, and a formed article having a deep depth (for example, having a depth that is deeper than a diameter of a cylinder or a cone, or a length of one side of a pyramid) is formed by the deep draw forming. Known techniques can be applied to the three-dimensional forming method.

### [Electronic Component]

One aspect of the present invention relates to an electronic component including the electromagnetic wave shielding material. Examples of the electronic component include an electronic component included in an electronic apparatus such as a mobile phone, a mobile information terminal, and a medical device, and various electronic components such as a semiconductor element, a capacitor, a coil, and a cable. The electromagnetic wave shielding material is three-dimensionally formed into any shape, for example, according to the shape of the electronic component, thereby capable of being disposed in the inside of the electronic component, or it is three-dimensionally formed into a shape of a cover material, thereby capable of being disposed as a cover material that covers the outside of the electronic component. Alternatively, it can be three-dimensionally formed into a tubular shape, thereby being disposed as a cover material that covers the outside of the cable.

### [Electronic Apparatus]

One aspect of the present invention relates to an electronic apparatus including the electromagnetic wave shielding material. Examples of the electronic apparatus include electronic apparatuses such as a mobile phone, a mobile information terminal, and a medical device, electronic apparatuses including various electronic components such as a semiconductor element, a capacitor, a coil, and a cable, and electronic apparatuses in which electronic components are mounted on a circuit board. Such an electronic apparatus can include the electromagnetic wave shielding material as a constitutional member of an electronic component included in the device. In addition, as a constitutional member of the electronic apparatus, the electromagnetic wave shielding material can be disposed in the inside of the electronic apparatus or can be disposed as a cover material that covers the outside of the electronic apparatus. Alternatively, it can be three-dimensionally formed into a tubular shape, thereby being disposed as a cover material that covers the outside of the cable.

Examples of the usage form of the electromagnetic wave shielding material include a usage form in which a semiconductor package on a printed board is coated with an electromagnetic wave shielding material. For example, “Electromagnetic wave shielding technology in a semiconductor package” (Toshiba Review Vol. 67, No. 2 (2012) P. 8) discloses a method of obtaining a high shielding effect by electrically connecting a side via of an end part of a package substrate and an inner surface of an electromagnetic wave shielding material in a case where a semiconductor package is coated with an electromagnetic wave shielding material, thereby carrying out ground wiring. In order to carry out such wiring, it is desirable that the outermost layer of the electromagnetic wave shielding material on the electronic component side is a metal layer. In a case where one or both of the outermost layers of the electromagnetic wave shielding material is a metal layer in the electromagnetic wave shielding material, the electromagnetic wave shielding material can be suitably used in a case of carrying out the wiring as described above.

### EXAMPLES

Hereinafter, the present invention will be described in more detail with reference to Examples. However, the present invention is not limited to the embodiments shown in Examples. Unless otherwise specified, the following various steps were performed at room temperature of 20° C. to 25° C.

### Example 1

### <Preparation of Composition for Forming Magnetic Layer (Coating Liquid)>

To a plastic bottle, the following substances were added and mixed with a shaking type stirrer for 1 hour to prepare a coating liquid;

100 g of magnetic particles (Sendust (Fe—Si—Al alloy) particles (MFS-SUH manufactured by MKT),

27.5 g of a polyurethane resin of a concentration of solid contents of 30% by mass (UR-6100, manufactured by TOYOBO Co., Ltd.),

0.5 g of a polyfunctional isocyanate (CORONATE L manufactured by Tosoh Corporation), and

233 g of cyclohexanone.

In a case where an average particle size of magnetic particles described above was measured by the method described above using transmission electron microscope H-9000 manufactured by Hitachi, Ltd. as a transmission electron microscope and image analysis software KS-400 manufactured by Carl Zeiss as image analysis software, the average particle size was 25 μm.

### <Production of Magnetic Layer>

While a peeling-treated PET film (PET75TR manufactured by NIPPA Co., Ltd., hereinafter also referred to as a “release film”) was continuously transported in a coating and drying device as follows, the coating liquid was applied and dried.

In a coating zone of the coating and drying device, the coating liquid was applied onto the peeling surface of the release film with a blade coater having a coating gap of 300 μm at a coating speed of 10 m/min to form a coating layer.

Thereafter, the release film on which the coating layer was formed was continuously transported to a first drying treatment zone and a second drying treatment zone of the coating and drying device.

In the first drying treatment zone, the initial drying was performed for 2 minutes by setting the atmospheric temperature of the atmosphere in the zone to the value shown in Table 1 and controlling the cyclohexanone gas concentration to the value shown in Table 1. The cyclohexanone gas concentration was controlled to the value shown in Table 1 by appropriately changing the amount of heated air newly taken into the atmosphere in the first drying treatment zone.

After the initial drying, the drying treatment was further performed for 20 minutes in the second drying treatment zone. The atmospheric temperature of the atmosphere in the second drying treatment zone was set to 80° C., and the cyclohexanone gas concentration was controlled to 0.01% by volume. The cyclohexanone gas concentration was controlled by appropriately changing the amount of heated air newly taken into the atmosphere in the second drying treatment zone.

In this way, a film-shaped magnetic layer was obtained.

The obtained magnetic layer was pressurized by the following method.

Upper and lower press plates of a plate-shape pressing machine (a large-scale hot press TA-200-1 W manufactured by YAMAMOTO ENG. WORKS Co., LTD.) were heated to 140° C. (the internal temperature of the press plate), and the magnetic layer on the release film was installed in the center of the press plate together with the release film and held for 10 minutes in a state where a pressure shown in Table 1 (in Table 1, “pressing pressure”) was applied. The upper and lower press plates were cooled to 50° C. (the internal temperature of the press plates) while maintaining the pressure, and then the magnetic layer was taken out together with the release film.

A part of the magnetic layer from which the release film was already peeled off was used as a sample piece for the following evaluation of the magnetic layer, and a part of the magnetic layer was used for producing the electromagnetic wave shielding material described below.

### <Measurement of Magnetic Permeability of Magnetic Layer>

For a rectangular sample piece having a size of 28 mm×10 mm cut out from the magnetic layer, the magnetic permeability was measured using a magnetic permeability measuring apparatus (PER01 manufactured by KEYCOM Corporation), and the magnetic permeability was determined as the real part (μ′) of the complex specific magnetic permeability at a frequency of 100 kHz (measurement temperature: 25° C.). The determined magnetic permeability was 148.

### <Measurement of Electrical Conductivity>

A cylindrical main electrode having a diameter of 30 mm was connected to the negative electrode side of a digital super-insulation resistance meter (TR-811A manufactured by Takeda RIKEN Industries), a ring electrode having an inner diameter of 40 mm and an outer diameter of 50 mm was connected to the positive electrode side thereof, the main electrode was installed on a sample piece of the magnetic layer cut to a size 60 mm×60 mm, the ring electrode was installed at a position surrounding the main electrode, a voltage of 25 V was applied to both electrodes, and the surface electrical resistivity of the magnetic layer alone was measured. The electrical conductivity of the magnetic layer was calculated from the surface electrical resistivity and the following expression. The calculated electrical conductivity was 1.1×10⁻² S/m.

As the thickness, the thickness of the magnetic layer, which had been determined according to the following method, was used.

$$Electrical conductivity [ S / m ] = 1 / ( surface electrical resisitivity [ Ω ] \times thickness [ m ] )$$

### <Production of Electromagnetic Wave Shielding Material>

Using the magnetic layer obtained above as the magnetic layer and using a copper foil (JIS H3100:2018 standard, alloy number: C1020R-H, Cu content: 99.9% by mass or more) having a thickness of 12 μm as the metal layer, three layers of “copper foil (metal layer)/magnetic layer/copper foil (metal layer)” were laminated to produce a laminate, without interposing other layers between two layers adjacent to each other.

Upper and lower press plates of a plate-shape pressing machine (a large-scale hot press TA-200-1 W manufactured by YAMAMOTO ENG. WORKS CO., LTD.) were heated to 140° C. (the internal temperature of the press plate), and the laminate was installed in the center of the press plate and held for 10 minutes in a state where a pressure of 4.66 N/mm² was applied, whereby the copper foil and the magnetic layer were subjected to the thermal compression bonding. The upper and lower press plates were cooled to 50° C. (the internal temperature of the press plates) while maintaining the pressure, and then the laminate was taken out from the plate-shape pressing machine.

The laminate was cut into a size of 150 mm×150 mm.

In this way, an electromagnetic wave shielding material of Example 1 was obtained. The electromagnetic wave shielding material of Example 1 had a multilayer structure of “copper foil (metal layer)/magnetic layer/copper foil (metal layer)”

Three electromagnetic wave shielding materials were produced by the above method for Example 1, and each of the electromagnetic wave shielding materials was used for the following evaluation (1), (2), or (3).

### Example 2

An electromagnetic wave shielding material was produced according to the method described for Example 1, except that the initial drying temperature of the coating layer of the composition for forming a magnetic layer was changed to the value shown in Table 1.

### Example 3

An electromagnetic wave shielding material was produced according to the method described for Example 1, except that the pressing pressure in the pressurization treatment of the magnetic layer was changed to the value shown in Table 1.

### Example 4

An electromagnetic wave shielding material was produced according to the method described for Example 1, except that a laminate in which a resin layer (PET film (Lumirror 25-T60, manufactured by Toray Industries, Inc.) having a thickness of 25 μm and a copper foil (JIS H3100:2018 standard, alloy number: C1020R-H, Cu content: 99.9% by mass or more) having a thickness of 12 μm were bonded to each other through an adhesive layer having a thickness of 20 μm was used instead of the copper foil. In the production of the electromagnetic wave shielding material of Example 4, the surface of the above-described laminate on the PET film side and the surface of the magnetic layer were made to face each other. As a result, an electromagnetic wave shielding material having the layer configuration shown in Table 2 was produced.

### Example 5

An electromagnetic wave shielding material was produced according to the method described for Example 4, except that in the production of the electromagnetic wave shielding material, the surface of the above-described laminate on the copper foil side and the surface of the magnetic layer were made to face each other. As a result, an electromagnetic wave shielding material having the layer configuration shown in Table 2 was produced.

### Comparative Example 1

An electromagnetic wave shielding material was produced according to the method described for Example 1, except that the initial drying temperature of the coating layer of the composition for forming a magnetic layer was changed to the value shown in Table 1.

### Comparative Example 2

An electromagnetic wave shielding material was produced according to the method described for Example 1, except that the cyclohexanone gas concentration in the atmosphere in which the initial drying of the coating layer of the composition for forming a magnetic layer is performed was changed to the value shown in Table 1.

### [Evaluation Method]

### (1) Thickness of Magnetic Layer

Cross-section processing was carried out to expose the cross-section of each electromagnetic wave shielding material of Examples and Comparative Examples by the following method.

A sample piece cut out from a region within 15.0 mm from at least one end surface of the electromagnetic wave shielding material to be measured to a size of 3 mm×3 mm was embedded in a resin, and a cross section of the sample piece was cut with an ion milling device (IM4000PLUS, manufactured by Hitachi High-Tech Corporation).

The cross-section of the sample piece, which had been exposed in this way, was observed with a scanning electron microscope (SU8220, manufactured by Hitachi High-Tech Corporation) under the conditions of an acceleration voltage of 2 kV and a magnification of 100 times to obtain a backscattered electron image. From the obtained image, the thicknesses of five randomly selected points of the magnetic layer were measured with the scale bar as a reference, and an arithmetic average of the thicknesses was defined as the thickness of the magnetic layer.

### (2) Measurement of Cross-Sectional Void Volume

The cross-sectional void volume of each of the electromagnetic wave shielding materials of Examples and Comparative Examples was obtained, according to the method described above. As a measuring device, an Autopore V 9620 pore distribution measuring device (manufactured by Micromeritics Instrument Corporation) was used, and a measurement cell having an internal volume of 5 mL (5 cc) was used as a measurement cell.

### (3) Evaluation of Electromagnetic Wave Shielding Performance (KEC Method)

Each of the electromagnetic wave shielding materials (size: 150 mm×150 mm) of Examples and Comparative Examples was subjected to a vibration application treatment under cyclic humidification by the following method.

A vibration testing machine and the electromagnetic wave shielding material were disposed in a humidity-controllable chamber, and a vibration application treatment of applying vibration by a sine wave having a frequency of 25 Hz and an amplitude of 1.5 mm was performed for 72 hours. The atmospheric temperature in which the vibration application treatment is performed was set to 25° C., and cyclic humidification of repeating a relative humidity of 20% and 80% was performed every 2 hours during the 72 hours of the vibration application treatment.

The electromagnetic wave shielding performance of each electromagnetic wave shielding material was evaluated by the following method before and after the vibration application treatment under the cyclic humidification.

An electromagnetic wave shielding material was installed between antennas of a KEC method evaluation device including a signal generator, an amplifier, a pair of magnetic field antennas, and a spectrum analyzer, and at a frequency of 100 kHz to 1 GHz, a ratio (unit: decibel (dB)) of the intensity of the received signal in a case where the electromagnetic wave shielding material was not present to the intensity of the received signal in a case where the electromagnetic wave shielding material was present was determined and denoted as the shielding performance. The operation was carried out for the magnetic field antenna to obtain the magnetic field wave shielding performance. KEC is an abbreviation for Kansai Electronic Industry Development Center.

The above results are shown in Table 1.

TABLE 1

| | | | | | Electromagnetic | | |
|---|---|---|---|---|---|---|---|
| | | | | | wave shielding | | |
| | | | | | material | Shielding performance | |
| | | | | | Cross- | | After vibration |
| | Initial drying | | | Magnetic | sectional | | application |
| | | Cyclohexanone | Pressing | layer | void | | treatment |
| | Temperature | gas concentration | pressure | Thickness | volume | Initial | under cyclic |
| | (° C.) | (% by volume) | (N/mm²) | (μm) | (mL/mm²) | (dB) | humidification (dB) |
| Example 1 | 60 | 0.4 | 4.66 | 32 | 0.102 | 15.3 | 14.8 |
| Example 2 | 90 | 0.4 | 4.66 | 33 | 0.231 | 15.2 | 13.9 |
| Example 3 | 60 | 0.4 | 15.00 | 28 | 0.038 | 15.5 | 15.3 |
| Example 4 | 60 | 0.4 | 4.66 | 30 | 0.123 | 15.1 | 14.6 |
| Example 5 | 60 | 0.4 | 4.66 | 31 | 0.110 | 14.2 | 13.8 |
| Comparative | 130 | 0.4 | 4.66 | 32 | 0.317 | 15.2 | 9.5 |
| Example 1 | | | | | | | |
| Comparative | 60 | 0.01 | 4.66 | 31 | 0.409 | 15.1 | 8.5 |
| Example 2 | | | | | | | |

Table 2 shows a layer configuration of each of the electromagnetic wave shielding materials of Examples and Comparative Examples.

TABLE 2

| | Layer configuration of electromagnetic wave |
|---|---|
| | shielding material |
| Example 1 | Copper foil/magnetic layer/copper foil |
| Example 2 | Copper foil/magnetic layer/copper foil |
| Example 3 | Copper foil/magnetic layer/copper foil |
| Example 4 | Copper foil/adhesive layer/resin layer/magnetic |
| | layer/resin layer/adhesive layer/copper foil |
| Example 5 | Resin layer/adhesive layer/copper foil/magnetic |
| | layer/copper foil/adhesive layer/resin layer |
| Comparative | Copper foil/magnetic layer/copper foil |
| Example 1 | |
| Comparative | Copper foil/magnetic layer/copper foil |
| Example 2 | |

From the results shown in Table 1, it can be confirmed that, in the electromagnetic wave shielding materials of Examples 1 to 5, the decrease in electromagnetic wave shielding performance after being subjected to a change in humidity and vibration is suppressed as compared with the electromagnetic wave shielding materials of Comparative Examples 1 and 2.

One aspect of the present invention is useful in the technical fields of various electronic components and various electronic apparatuses.

What is claimed is:

1. An electromagnetic wave shielding material comprising:
a magnetic layer provided between two metal layers,
wherein a void volume of the electromagnetic wave shielding material is 0.240 mL/mm² or less as a value per 1 mm² of a unit cross-sectional area of the magnetic layer.

2. The electromagnetic wave shielding material according to claim 1,
wherein the magnetic layer contains magnetic particles and a resin.

3. The electromagnetic wave shielding material according to claim 1,
wherein the two metal layers are layers each directly in contact with the magnetic layer.

4. The electromagnetic wave shielding material according to claim 1,
wherein both outermost layers are the metal layers.

5. The electromagnetic wave shielding material according to claim 1,
wherein the void volume of the electromagnetic wave shielding material is 0.030 mL/mm² or more and 0.240 mL/mm² or less as the value per 1 mm² of the unit cross-sectional area of the magnetic layer.

6. The electromagnetic wave shielding material according to claim 1,
wherein the magnetic layer contains magnetic particles and a resin,
the two metal layers are layers each directly in contact with the magnetic layer,
both outermost layers are the metal layers, and
the void volume of the electromagnetic wave shielding material is 0.030 mL/mm² or more and 0.240 mL/mm² or less as the value per 1 mm² of the unit cross-sectional area of the magnetic layer.

7. An electronic component comprising:
the electromagnetic wave shielding material according to claim 1.

8. The electronic component according to claim 7,
wherein the magnetic layer contains magnetic particles and a resin.

9. The electronic component according to claim 7,
wherein the two metal layers are layers each directly in contact with the magnetic layer.

10. The electronic component according to claim 7,
wherein both outermost layers of the electromagnetic wave shielding material are the metal layers.

11. The electronic component according to claim 7,
wherein the void volume of the electromagnetic wave shielding material is 0.030 mL/mm² or more and 0.240 mL/mm² or less as the value per 1 mm² of the unit cross-sectional area of the magnetic layer.

12. The electronic component according to claim 7,
wherein the magnetic layer contains magnetic particles and a resin,
the two metal layers are layers each directly in contact with the magnetic layer,
both outermost layers of the electromagnetic wave shielding material are the metal layers, and
the void volume of the electromagnetic wave shielding material is 0.030 mL/mm² or more and 0.240 mL/mm² or less as the value per 1 mm² of the unit cross-sectional area of the magnetic layer.

13. An electronic apparatus comprising:
the electromagnetic wave shielding material according to claim 1.

14. The electronic apparatus according to claim 13,
wherein the magnetic layer contains magnetic particles and a resin.

15. The electronic apparatus according to claim 13,
wherein the two metal layers are layers each directly in contact with the magnetic layer.

16. The electronic apparatus according to claim 13,
wherein both outermost layers of the electromagnetic wave shielding material are the metal layers.

17. The electronic apparatus according to claim 13,
wherein the void volume of the electromagnetic wave shielding material is 0.030 mL/mm² or more and 0.240 mL/mm² or less as the value per 1 mm² of the unit cross-sectional area of the magnetic layer.

18. The electronic apparatus according to claim 13,
wherein the magnetic layer contains magnetic particles and a resin,
the two metal layers are layers each directly in contact with the magnetic layer,
both outermost layers of the electromagnetic wave shielding material are the metal layers, and
the void volume of the electromagnetic wave shielding material is 0.030 mL/mm² or more and 0.240 mL/mm² or less as the value per 1 mm² of the unit cross-sectional area of the magnetic layer.
